(19) United States
(12) Patent Application Publication
(10) Pub. No.: US 2006/0134882 A1
(43) Pub. Date: Jun. 22, 2006

(54) Method to improve device isolation via fabrication of deeper shallow trench isolation regions

(75) Inventor: Guowei Zhang, Singapore (SG)

Correspondence Address: STEPHEN B. ACKERMAN, 28 DAVIS AVENUE, POUGHKEEPSIE, NY, 12603, US

(73) Assignee: Chartered Semiconductor Manufacturing Ltd.

(21) Appl. No.: 11/021,030

(22) Filed: Dec. 22, 2004

(51) Int. Cl. H01L 21/76

(52) U.S. Cl. 438/424

(57) ABSTRACT

A method of forming a shallow trench isolation (STI) structure wherein the depth of the STI structure has been extended via formation of an underlying silicon oxide region, has been developed. After definition of a shallow trench isolation shape in a top portion of a semiconductor substrate a self-aligned ion implantation procedure is employed to place oxygen ions in portions of the semiconductor substrate exposed at the bottom portion of the shallow trench shape. Growth of a liner layer on the exposed surfaces of the shallow trench shape, or growth of a liner layer followed by anneal procedure, results in activation of the implanted oxygen ions creating the desired silicon oxide region in a portion of the semiconductor substrate underlying the bottom of the shallow trench shape. Insulator filling of the shallow trench shape now results in a deeper STI structure comprised of the insulator filled shallow trench shape and the underlying silicon oxide region.

### BACKGROUND OF THE INVENTION

(1) Field of the Invention

The present invention relates to methods used to fabricate semiconductor devices and more specifically to a method used to increase the depth of a shallow trench isolation (STI) region without increasing the depth of a shallow trench shape.

(2) Description of Prior Art

Isolation between semiconductor devices as well as between specific elements of semiconductor devices has been accomplished via shallow trench isolation structures comprised of insulator filled, shallow trench shapes. Increased STI depth allows greater reductions of device leakage current and of device noise cross-talk to be realized while also allowing increased device latch up performance to occur. One method of increasing STI depth, and thus enhanced device performance, is the fabrication of deeper STI shapes in a semiconductor substrate achieved via longer dry etching procedures. The more robust dry etch procedure can however lead to defect generation in adjacent semiconductor regions. In addition deeper and narrower STI openings result in large aspect ratios making insulator filling of the large aspect ratio STI shapes difficult to accomplish.

The present invention will teach a novel procedure for increasing the depth of STI structures however without increasing the depth or the aspect ratio of the dry etched shallow trench shapes, thus allowing the desired lower device leakage levels and increased device latch up to be accomplished without the vulnerabilities presented with the deeper, dry etched shallow trench shapes. Prior art such as Cha et al in U.S. Pat. No. 6,680,239 as well as Lin et al in U.S. Pat. No. 6,576,558 describe methods of forming STI regions in a semiconductor substrate, however none of the above prior art describe the novel process described in the present invention in which the depth of a STI region is increased without increasing the depth of the dry etched shallow trench shape.

### SUMMARY OF THE INVENTION

It is an object of this invention to fabricate an insulator filled shallow trench isolation (STI) structure in a semiconductor substrate.

It is another object of this invention to perform a self aligned, oxygen ion implantation procedure in exposed portions of a dry etched shallow trench shape.

It is still another object of this invention to form a silicon oxide region at the bottom portion of the shallow trench shape prior to insulator refill via annealing of the implanted oxygen ions to increase the depth of a subsequently formed insulator filled STI structure.

In accordance with the present invention a method of forming an STI structure in a semiconductor substrate wherein the depth of the insulator filled STI structure is extended by a silicon oxide region formed below a pre-insulator filled STI shape via a self aligned oxygen implantation and anneal procedure, is described. Via use of a photoresist mask and dry etch procedures an opening is formed in an overlying silicon nitride layer and an underlying silicon oxide layer, with the dry etch procedure continued to form a shallow trench shape in a top portion of a semiconductor substrate. An ion implantation procedure is next used to self align oxygen ions into portions of the semiconductor substrate exposed at the bottom of the shallow trench shape. Removal of the photoresist shape is followed by oxidation and anneal procedures wherein the oxidation procedure forms a liner silicon oxide layer on the exposed surfaces of the shallow trench shape, while the anneal procedure allows a silicon oxide region to be established in the portion of semiconductor substrate comprised with the implanted oxygen ions. Insulator filling of the shallow trench shape followed by removal of unwanted portions of the insulator fill layer result in an STI structure comprised of an insulator filled shallow trench shape and an underlying silicon oxide region established via a self aligned oxygen implantation and anneal procedure.

### BRIEF DESCRIPTION OF THE DRAWINGS

The object and other advantages of this invention are best described in the preferred embodiment with reference to the attached drawings which include:

FIGS. 1-8, which schematically in cross-sectional style describe key stages in the fabrication of an STI structure wherein the depth of the insulator filled STI structure is extended by a silicon oxide region formed below a pre-insulator filled STI shape via a self aligned oxygen implantation and anneal procedure.

### DESCRIPTION OF THE PREFERRED EMBODIMENTS

The method of forming an STI structure wherein the depth of the insulator filled STI structure is extended with a silicon oxide region formed below a pre-insulator filled STI shape via a self aligned oxygen implantation and anneal procedure, will now be described in detail. Semiconductor substrate 1, comprised of single crystalline silicon featuring a <100> crystallographic orientation, is shown schematically in FIG. 1. Silicon oxide layer 2, either thermally grown, or obtained via low pressure chemical vapor deposition (LPCVD) or plasma enhanced chemical vapor deposition (PECVD) procedures at a thickness between about 80 to 120 Angstroms, is next formed on semiconductor substrate 1. Silicon nitride layer 3, at a thickness between about 1400 to 1800 Angstroms, is now deposited via LPCVD or PECVD procedures.

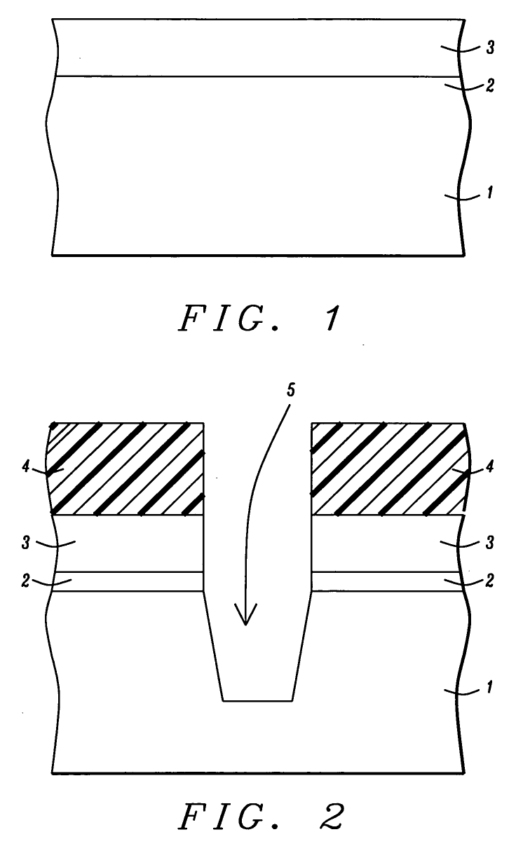

Photoresist shape 4, is next formed with a defined opening between about 0.2 to 1.0 micrometers (um), exposing a portion of the top surface of silicon nitride layer 3. A first stage of a dry etch procedure is next performed to remove exposed portions of silicon nitride layer 3, and of silicon oxide layer 2. The first stage of the dry etch procedure is reactive ion etch (RIE) procedure, anisotropically performed using CF₄ or CHF₃ as an etchant to form the straight walled portion of opening 5. At the appearance of the top surface of semiconductor substrate 1, a second stage of the dry etch procedure is performed to form a shallow trench shape in a top portion of semiconductor substrate 1. This is again accomplished via a RIE procedure using Cl₂ as an etchant, with the pressure of the second stage of the dry etch procedure increased to allow a tapered shallow trench shape to be defined in the top portion of semiconductor substrate 1, at a depth between about 3800 to 4200 Angstroms. Opening 5, is now comprised of a straight walled component in silicon nitride layer 3, and in silicon oxide layer 2, and an underlying shallow trench shape component in the top portion of semiconductor substrate 1, with a taper of the shallow trench shape between about 75 to 90 degrees. This is schematically shown in FIG. 2.

With photoresist shape 4, in place a critical oxygen ion implantation procedure is employed placing oxygen ions 6a, in exposed regions of the shallow trench shape. The ion implantation procedure is performed at an energy between about 50 to 200 KeV, at a dose between about 1E17 to 1E19 atoms/cm², using an implant angle of 0 degrees. The ion implantation procedure is self aligned to the opening in photoresist shape 4, placing oxygen ions 6a, only in portions of semiconductor substrate 1, exposed at the bottom of, and in the tapered sides of opening 5. This is schematically described in FIG. 3. The concentration of oxygen ions 6a, decreases along the tapered sides of the shallow trench shape decreases from the bottom to top.

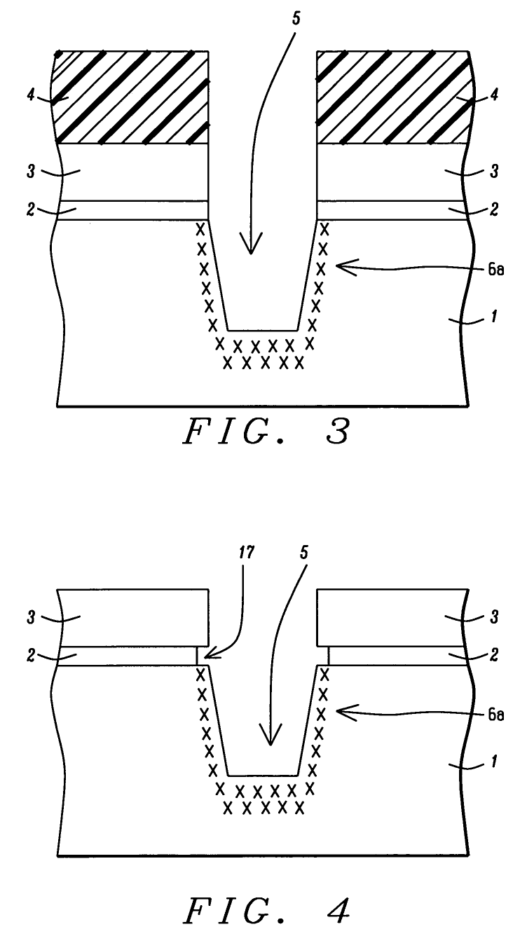

Photoresist shape 4, in next removed via plasma oxygen ashing procedures. A photoresist post-clean and pre-liner oxidation procedure is now performed using either a dilute hydrofluoric (DHF) or a buffered hydrofluoric (BHF) acid component. The clean procedure in addition to removing contaminants as well as oxide formed during the plasma ashing procedure, results in lateral etching of silicon oxide layer 2, exposed in opening 5. Groove or gap 7, in silicon oxide layer 2, results from the above clean procedures is schematically shown in FIG. 4.

A procedure to line the exposed surfaces of the shallow trench shape of opening 5, and to fill groove 7, is next addressed via a thermal oxidation procedure performed at a temperature between about 1100 to 1200° C., in an oxygen or in an oxygen-steam ambient. Liner silicon oxide layer is formed at a thickness between about 100 to 250 Angstroms. This is schematically shown in FIG. 5.

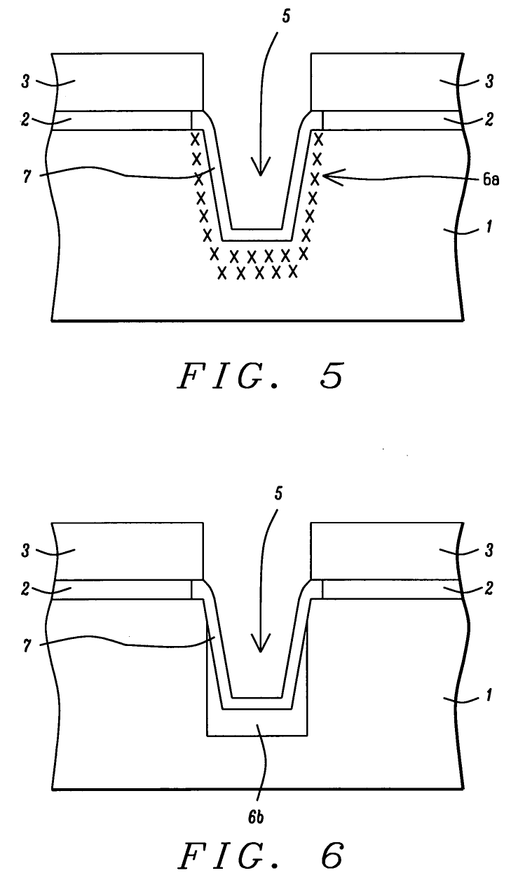

An anneal procedure is next performed in an inert ambient such as nitrogen, at a temperature between about 1100 to 1300° C., for a time between about 50 to 60 min., resulting in activation of oxygen ions 6a, and in the formation of silicon oxide region 6b. A first portion of silicon oxide region 6b, is formed underlying the bottom of the silicon oxide lined shallow trench opening at a thickness between about 1000 to 9000 Angstroms. The anneal procedure also results formation of a second portion of silicon oxide region 6b, along the tapered sides of the silicon oxide lined shallow trench shape. The thickness of the second portion of silicon oxide region 6b, is proportional to the concentration of oxygen ions present, therefore resulting in increasing silicon oxide thickness with decreasing depth of the shallow trench shape. This results in a straight walled, silicon oxide region 6b, surrounding the silicon oxide lined shallow trench shape. This is shown schematically in FIG. 6. If desired the liner oxidation and anneal procedures can both be accomplished during a single procedure with the temperature of the liner oxidation procedure performed at a temperature between about 1100 to 1300° C., sufficient to allow formation of silicon oxide region 6b, to be formed.

An insulator layer such as silicon oxide is next used to fill opening 5. Insulator layer 8, is obtained via LPCVD or via PECVD procedures at a thickness between about 7200 to 7800 Angstroms, completely filling opening 5, in addition to forming on the top surface of silicon nitride layer 3. Removal of unwanted portions of insulator layer 8, is accomplished via a chemical mechanical polishing (CMP) procedure which selectively terminates at the top surface of silicon nitride layer 3. If desired a selective dry etch procedure, using CF₄ as an etchant for insulator layer 8, can also be employed to remove unwanted portions of insulator layer 8. This is schematically shown in FIG. 7.

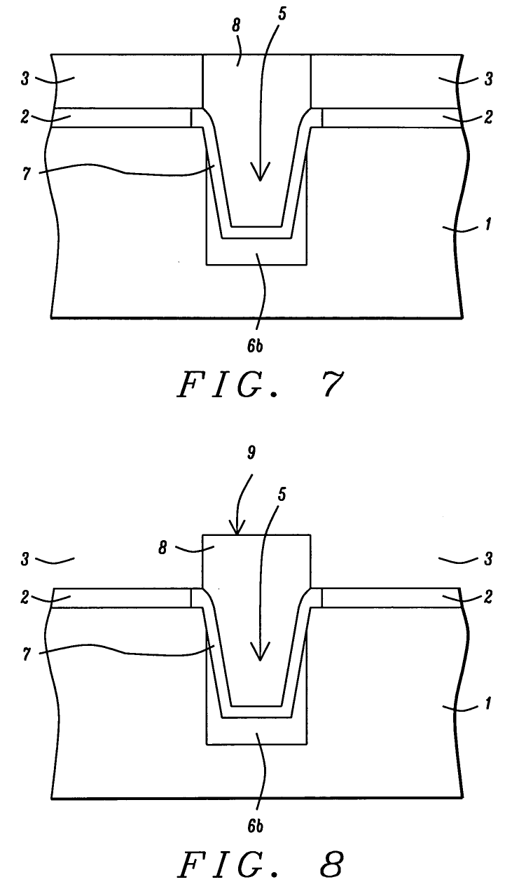

Removal of silicon nitride layer 3, is next addressed via use of a selective hot phosphoric acid solution, or via a selective dry etch procedure employing Cl₂ as an etchant for silicon nitride. The resulting shallow trench isolation (STI) structure 9, shown schematically in FIG. 8, is now comprised of the insulator filled shallow trench shape, and of underlying silicon oxide region 6b. The presence of underlying STI component silicon oxide region 6b, allows the depth of STI structure 9, to be extended deeper than the depth of the dry etched shallow trench shape. The increased depth of STI structure 9, resulting from formation of oxygen implanted silicon oxide region 6b, allowed the desired deeper STI structure 9, to be accomplished without additional dry etching of semiconductor substrate.

While this invention has been particularly shown and described with reference to the preferred embodiments thereof, it will be understood by those skilled in the art that various changes in form and details may be made without departing from the spirit or scope of the invention.

What is claimed is:

1. A method of forming a shallow trench isolation (sti) structure in a semiconductor: substrate, comprising the steps of:
providing on a hard mask insulator layer and an underlying first insulator layer on said semiconductor substrate;
forming a first opening in said hard mask layer and in said first insulator layer;
forming a second opening in a top portion of said semiconductor substrate;
performing an ion implantation procedure to place oxygen ions into portions of said semiconductor substrate exposed at bottom of said second opening, and into sides of said semiconductor substrate exposed in said second opening;
growing a liner insulator layer on surfaces of said semiconductor substrate exposed in said second opening, with the procedure used to grow said liner layer activating said oxygen ions forming a silicon oxide region in portions of said semiconductor substrate exposed at bottom of, and sides of said second opening; and
depositing a second insulator layer to fill said first opening and in said second opening, resulting in said STI structure comprised of said second insulator and comprised of an underlying silicon oxide region.

2. The method of claim 1, wherein said hard mask layer is a silicon nitride layer obtained via low pressure chemical vapor deposition (LPCVD) or via plasma enhanced chemical vapor deposition (PECVD) procedures, at a thickness between about 1400 to 1800 Angstroms.

3. The method of claim 1, wherein said underlying first insulator layer is a silicon oxide layer obtained via thermal oxidation procedures or LPCVD or PECVD procedures, at a thickness between about 80 to 120 Angstroms.

4. The method of claim 1, wherein said second opening in a top portion of said semiconductor substrate is a shallow trench shape, obtained via a reactive ion etching procedure using Cl₂ as an etchant.

5. The method of claim 1, wherein said second opening in a top portion of said semiconductor substrate is formed at a depth between about 3800 to 4200 Angstroms, and comprised with sides featuring a taper between about 75 to 90 degrees.

6. The method of claim 1, wherein said ion implantation procedure is an oxygen ion implantation procedure, performed at an energy between about 50 to 200 KeV, at a dose between about 1E17 to 1E19 atoms/cm², using an implant angle of 0 degrees.

7. The method of claim 1, wherein said liner layer is a silicon oxide layer comprised with a thickness between about 100 to 250 Angstroms.

8. The method of claim 1, wherein said liner layer is obtained via thermal oxidation procedures, performed in an oxygen or in an oxygen-steam ambient at a temperature between about 1100 to 1200° C.

9. The method of claim 1, wherein said silicon oxide region, located below said second opening, is formed at a thickness between about 1000 to 9000 Angstroms.

10. The method of claim 1, wherein said second insulator layer is a silicon oxide layer obtained via LPCVD or PECVD procedures at a thickness between about 7200 to 7800 Angstroms.

11. A method of forming a shallow trench isolation (STI) structure in a semiconductor substrate wherein the depth of said STI structure is greater than the depth of a shallow trench shape defined in said semiconductor substrate, comprising the steps of:
forming a first silicon oxide layer;
forming a silicon nitride layer;
performing a first dry etch procedure using a photoresist shape as an etch mask, to form an opening in said silicon nitride and said first silicon oxide layer;
performing a second dry etch procedure using said photoresist shape as an etch mask, to define said shallow trench shape featuring tapered sides in a top portion of said semiconductor substrate;
using said photoresist shape as a mask performing an ion implantation procedure to place oxygen ions into portions of said semiconductor substrate exposed at bottom of said shallow trench shape and into tapered sides of said semiconductor substrate exposed in said shallow trench shape;
growing a silicon oxide liner layer on surfaces of said semiconductor substrate exposed in said shallow trench shape;
performing an anneal procedure to activate said oxygen ions forming a silicon oxide region in portions of said semiconductor substrate exposed at bottom of, and on tapered sides of said shallow trench shape;
depositing a second silicon oxide layer completely filling said shallow trench shape;
selectively removing portions of said second silicon oxide from tp surface of said silicon nitride layer; and
selectively removing said silicon nitride layer.

12. The method of claim 11, wherein said first silicon oxide layer is obtained via thermal oxidation procedures or LPCVD or PECVD procedures, at a thickness between about 80 to 120 Angstroms.

13. The method of claim 11, wherein said silicon nitride layer is obtained via LPCVD or via PECVD procedures, at a thickness between about 1400 to 1800 Angstroms.

14. The method of claim 11, wherein said first dry etch procedure is an anisotropic reactive ion etch (RIE) procedure performed using CF₄ or CHF₃ as an etchant.

15. The method of claim 11, wherein said second dry etch procedure is a RIE procedure performed using Cl₂ as an etchant to form said shallow trench shape in a top portion of said semiconductor substrate.

16. The method of claim 11, wherein said shallow trench shape is formed to a depth between about 3800 to 4200 Angstroms, and comprised with sides featuring a taper between about 75 to 90 degrees.

17. The method of claim 11, wherein said ion implantation procedure is an oxygen ion implantation procedure performed at an energy between about 50 to 200 KeV, at a dose between about 1E17 to 1E19 atoms/cm², using an implant angle of 0 degrees.

18. The method of claim 11, wherein said silicon oxide liner is formed at a thickness between about 100 to 250 Angstrom via thermal oxidation procedures performed in an oxygen or in an oxygen-steam ambient at a temperature between about 1100 to 1200° C.

19. The method of claim 11, wherein said anneal procedure is performed at a temperature between about 1100 to 1300° C., for a time between about 50 to 60 min, in an inert ambient.

20. The method of claim 11, wherein said silicon oxide region, located below said shallow trench shape, is formed at a thickness between about 1000 to 9000 Angstroms.

21. The method of claim 11, wherein said silicon oxide layer is obtained via LPCVD or PECVD procedures at a thickness between about 7200 to 7800 Angstroms.

22. A shallow trench isolation (STI) structure in a semiconductor substrate, comprising:
an shallow trench shape with tapered sides, located in a top portion of said semiconductor substrate;
a silicon oxide liner layer located on tapered sides and on bottom of said shallow trench shape;
a silicon oxide shape featuring a first portion of said first silicon oxide shape located entirely in said shallow trench shape interfacing underlying said silicon oxide liner layer, and featuring a second portion of said silicon oxide shape located overlying said first silicon oxide shape; and
a silicon oxide region featuring a first portion of said silicon region located directly below bottom of said first portion of said silicon oxide shape, and a second portion of said silicon oxide region interfacing portions of said silicon oxide liner layer located on tapered sides of said shallow trench shapes, with thickness of said second portion of said silicon oxide region decreasing with decreasing depth of said shallow trench shape, resulting in a silicon oxide region comprised with straight sides.

23. The STI structure of claim 22, wherein said shallow trench shape is comprised with a depth in a top portion of said semiconductor substrate between about 3800 to 4200 Angstroms.

24. The STI structure of claim 22, wherein the sides of said shallow trench shape are tapered to an angle between about 75 to 90 degrees.

25. The STI structure of claim 22, wherein said silicon oxide liner layer is comprised with a thickness between about 100 to 250 Angstroms.

26. The STI structure of claim 22, wherein said second portion of said silicon oxide region is comprised with a thickness between about 7200 to 7800 Angstroms.
